(19) United States
(12) Patent Application Publication
(10) Pub. No.: US 2025/0217378 A1
(43) Pub. Date: Jul. 3, 2025

(54) DATA PROCESSING SYSTEM AND DATA PROCESSING METHOD

(71) Applicant: SEMICONDUCTOR ENERGY LABORATORY CO., LTD., Atsugi-shi (JP)

(72) Inventors: Kiyotaka KIMURA, Isehara (JP); Ryo NAKAZATO, Ebina (JP); Naoaki TSUTSUI, Atsugi (JP)

(21) Appl. No.: 18/999,247

(22) Filed: Dec. 23, 2024

(30) Foreign Application Priority Data
Dec. 27, 2023 (JP) 2023-220980

(51) Int. Cl. G06F 16/248; G06F 16/2455; G06F 30/3308

(52) U.S. Cl. CPC G06F 16/248; G06F 16/2455; G06F 30/3308

(57) ABSTRACT

A novel data processing system that is highly convenient, useful, or reliable is provided. The data processing system is composed of three components. A first component receives characteristic information, creates a query via a preprocessing portion and a conversion portion, and transfers the query to a second component. The characteristic information includes a response curve, the preprocessing portion converts the response curve into a normalized curve, and the conversion portion converts the normalized curve into a feature vector. The second component receives the query, obtains a search result from a database using a search engine, and transfers the search result to a third component. The search result includes circuit design information in some cases. The third component receives the search result and makes a report. The report includes the circuit design information.

### BACKGROUND OF THE INVENTION

### 1. Field of the Invention

One embodiment of the present invention relates to a data processing system and a data processing method.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting device, a power storage device, a memory device, a method for driving any of them, and a method for manufacturing any of them.

### 2. Description of the Related Art

A search system and a search method that include a means to input first circuit diagram information to a terminal, a database in which second circuit diagram information is registered, a means to convert the input first circuit diagram information into a first graph, an arithmetic means to calculate similarity between the first graph and a second graph based on the second circuit diagram information, and a means to display the similarity on the terminal are known (Patent Document 1).

### REFERENCE

[Patent Document 1] PCT International Publication No. WO2020/229927

### SUMMARY OF THE INVENTION

An object of one embodiment of the present invention is to provide a novel data processing system that is highly convenient, useful, or reliable. Another object is to provide a novel data processing method that is highly convenient, useful, or reliable. Another object is to provide a novel data processing system, a novel data processing method, or a novel semiconductor device.

Note that the description of these objects does not preclude the existence of other objects. In one embodiment of the present invention, there is no need to achieve all of these objects. Other objects will be apparent from and can be derived from the description of the specification, the drawings, the claims, and the like.

(1) One embodiment of the present invention is a data processing system including a first component, a second component, and a third component.

The first component has a function of receiving characteristic information, includes a preprocessing portion and a conversion portion, and has a function of creating a query and transferring the query to the second component.

The characteristic information includes a first response curve, and the first response curve includes an independent variable and a dependent variable.

The preprocessing portion has a function of converting the first response curve into a normalized curve.

The conversion portion has a function of selecting a converter on the basis of a combination of the independent variable and the dependent variable. The converter has a function of converting the normalized curve into a first feature vector. The normalized curve includes the independent variable normalized in a first predetermined range and the dependent variable normalized in a second predetermined range.

The query transferred to the second component includes the first feature vector.

The second component has a function of receiving the query, performing processing using a search engine, and transferring a search result to the third component.

The search engine has a function of obtaining the search result from a database in accordance with the query. The database stores a record, and the record includes circuit design information and a second feature vector associated with the circuit design information. Note that the search result includes the circuit design information associated with the second feature vector similar to the first feature vector.

The third component has a function of receiving the search result and making a report. The report includes the circuit design information.

Thus, the database can be searched using the first response curve. In addition, circuit design information of a circuit that performs an operation similar to the operation represented by the first response curve can be found from the database. For example, design information of a circuit designed in the past can be stored in the database and the circuit design information of the circuit that performs the operation similar to the operation represented by the first response curve can be found. For example, circuit design information disclosed in a document can be stored in the database and the circuit design information of the circuit that performs the operation similar to the operation represented by the first response curve can be found. In addition, the past knowledge can be effectively used. As a result, a novel data processing system that is highly convenient, useful, or reliable can be provided.

(2) Another embodiment of the present invention is the data processing system in which the circuit design information includes a circuit diagram.

(3) Another embodiment of the present invention is the data processing system in which the circuit design information includes a second response curve of an electronic circuit shown in the circuit diagram, and the report includes the circuit diagram and the second response curve.

Thus, a circuit diagram of a circuit that performs an operation similar to the operation represented by the first response curve can be found from the database. The second response curve can be viewed. For example, a circuit diagram of a circuit designed in the past can be stored in the database and the circuit diagram of the circuit that performs the operation similar to the operation represented by the first response curve can be found from the database. The second response curve can be viewed. For example, the circuit design information disclosed in a document can be stored in the database and the circuit diagram of the circuit that performs the operation similar to the operation represented by the first response curve can be found. The second response curve can be viewed. In addition, the past knowledge can be effectively used. As a result, a novel data processing system that is highly convenient, useful, or reliable can be provided.

(4) Another embodiment of the present invention is the data processing system including a fourth component and a fifth component.

The fourth component has a function of receiving a device model, transferring the device model to the fifth component, receiving the report, and providing the report.

The fifth component has a function of receiving the device model, performing processing using an electronic circuit simulator, and transferring the characteristic information to the first component. The electronic circuit simulator has a function of generating the characteristic information from the device model.

The third component has a function of transferring the report to the fourth component.

Thus, the first response curve can be generated using the electronic circuit simulator. The first response curve can be generated from the device model. The database can be searched using the generated first response curve. In addition, circuit design information of a circuit that performs an operation similar to the operation represented by the first response curve can be found from the database. The report including the circuit design information found from the database can be displayed on the fourth component. In addition, the past knowledge can be effectively used. As a result, a novel data processing system that is highly convenient, useful, or reliable can be provided.

(5) Another embodiment of the present invention is the data processing system in which the fourth component has a function of receiving a narrowing condition and transferring the narrowing condition to the first component, the first component has a function of receiving the narrowing condition, and the query includes the narrowing condition.

Accordingly, the circuit design information of the circuit that performs the operation similar to the operation represented by the generated first response curve can be found from the database, and then the circuit design information that satisfies the narrowing condition can be found. The report including the circuit design information found from the database can be displayed on the fourth component. In addition, the past knowledge can be effectively used. As a result, a novel data processing system that is highly convenient, useful, or reliable can be provided.

(6) Another embodiment of the present invention is a data processing method including first to sixth steps.

In the first step, a first component receives characteristic information. The characteristic information includes a response curve, and the response curve includes an independent variable and a dependent variable.

In the second step, the first component selects a converter on the basis of a combination of the independent variable and the dependent variable. The converter has a function of converting the response curve into a first feature vector.

In the third step, the first component creates a query and transfers the query to a second component. The query includes the first feature vector.

In the fourth step, the second component receives the query and obtains a search result from a database in accordance with the query using a search engine. The database stores a record, and the record includes circuit design information and a second feature vector associated with the circuit design information. Note that the search result includes the circuit design information associated with the second feature vector similar to the first feature vector.

In the fifth step, the second component transfers the search result to a third component.

In the sixth step, the third component receives the search result and makes a report from the search result. The report includes the circuit design information.

Thus, the database can be searched using the response curve. In addition, circuit design information of a circuit that performs an operation similar to the operation represented by the response curve can be found from the database. For example, design information of a circuit designed in the past can be stored in the database and the circuit design information of the circuit that performs the operation similar to the operation represented by the response curve can be found. For example, the circuit design information disclosed in a document can be stored in the database and the circuit design information of the circuit that performs the operation similar to the operation represented by the response curve can be found. In addition, the past knowledge can be effectively used. As a result, a novel data processing method that is highly convenient, useful, or reliable can be provided.

(7) Another embodiment of the present invention is a data processing method including first to eleventh steps.

In the first step, a first component receives a device model and transfers the device model to a second component.

In the second step, the second component receives the device model and generates a response curve using an electronic circuit simulator.

In the third step, the second component transfers the response curve to a third component.

In the fourth step, the third component receives characteristic information. The characteristic information includes the response curve, and the response curve includes an independent variable and a dependent variable.

In the fifth step, the third component selects a converter on the basis of a combination of the independent variable and the dependent variable. The converter has a function of converting the response curve into a first feature vector.

In the sixth step, the third component creates a query and transfers the query to a fourth component. The query includes the first feature vector.

In the seventh step, the fourth component receives the query and obtains a search result from a database in accordance with the query using a search engine. The database stores a record, and the record includes circuit design information and a second feature vector associated with the circuit design information. Note that the search result includes the circuit design information associated with the second feature vector similar to the first feature vector.

In the eighth step, the fourth component transfers the search result to a fifth component.

In the ninth step, the fifth component receives the search result and makes a report from the search result. The report includes the circuit design information.

In the tenth step, the fifth component transfers the report to the first component.

In the eleventh step, the first component receives and provides the report.

Thus, the response curve can be generated using the electronic circuit simulator. The response curve can be generated from the device model. In addition, the database can be searched using the generated response curve. In addition, circuit design information of a circuit that performs an operation similar to the operation represented by the generated response curve can be found from the database. The report including the circuit design information found from the database can be displayed on the first component. In addition, the past knowledge can be effectively used. As a result, a novel data processing method that is highly convenient, useful, or reliable can be provided.

Although the block diagram in drawings attached to this specification shows components classified based on their functions in independent blocks, it is difficult to classify actual components based on their functions completely, and one component can have a plurality of functions.

One embodiment of the present invention can provide a novel data processing system that is highly convenient, useful, or reliable. Another embodiment of the present invention can provide a novel data processing method that is highly convenient, useful, or reliable. Furthermore, a novel data processing system can be provided. Furthermore, a novel data processing method can be provided.

Note that the description of these effects does not preclude the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

In the accompanying drawings:

FIG. 1 illustrates a structure of a data processing system of an embodiment;

FIG. 2A illustrates a structure of a component used for a data processing system of an embodiment, and FIG. 2B illustrates part of the component;

FIG. 3A illustrates a normalized curve used for a data processing system of an embodiment, and FIG. 3B illustrates part of the component;

FIG. 4A illustrates a normalized curve used for a data processing system of an embodiment, and FIG. 4B illustrates part of the component;

FIG. 5A illustrates a structure of a component used for a data processing system of an embodiment, and FIG. 5B illustrates part of the component;

FIG. 6 illustrates a structure of a data processing system of an embodiment;

FIG. 7A illustrates a device model, FIG. 7B shows a response curve representing operation characteristics of the device model, and FIG. 7C shows a normalized curve;

FIGS. 8A to 8C illustrate circuit diagrams included in a report of an embodiment;

FIGS. 9A to 9D each show a device model and a response curve representing its operation characteristics;

FIG. 10 illustrates a structure of a data processing device used for a data processing system of an embodiment;

FIG. 11 illustrates a data processing method of an embodiment; and

FIG. 12 illustrates a data processing method of an embodiment.

### DETAILED DESCRIPTION OF THE INVENTION

The data processing system of one embodiment of the present invention includes a first component, a second component, and a third component.

The first component has a function of receiving characteristic information, includes a preprocessing portion and a conversion portion, and has a function of creating a query and transferring the query to the second component. The characteristic information includes a first response curve, and the first response curve includes an independent variable and a dependent variable. The preprocessing portion has a function of converting the first response curve into a normalized curve, the conversion portion has a function of selecting a converter on the basis of a combination of the independent variable and the dependent variable, and the converter has a function of converting the normalized curve into a first feature vector. Note that the normalized curve includes a normalized independent variable in a predetermined range and a normalized dependent variable in a predetermined range. The query includes the first feature vector.

The second component has a function of receiving the query, performing processing using a search engine, and transferring a search result to the third component. The search engine has a function of obtaining the search result from a database in accordance with the query, the database stores a record, and the record includes circuit design information and a second feature vector associated with the circuit design information. Note that when the second feature vector is similar to the first feature vector, the search result includes the circuit design information.

The third component has a function of receiving the search result and making a report, and the report includes the circuit design information.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

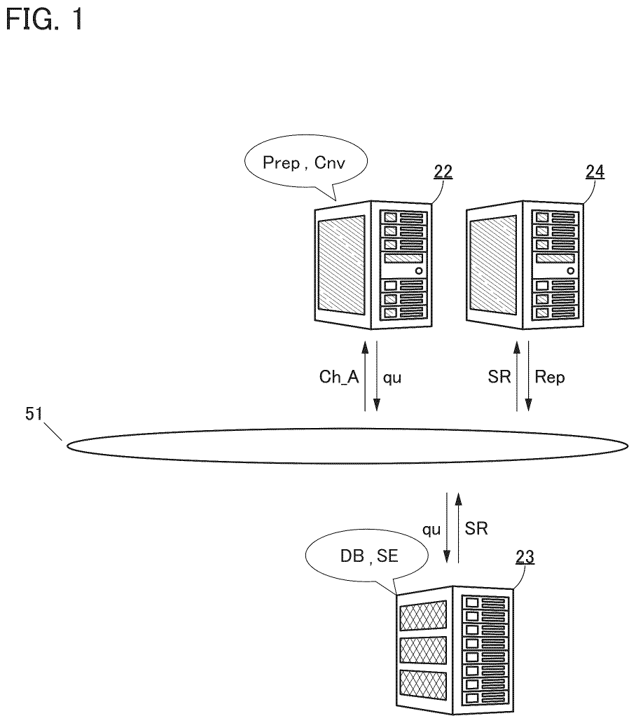

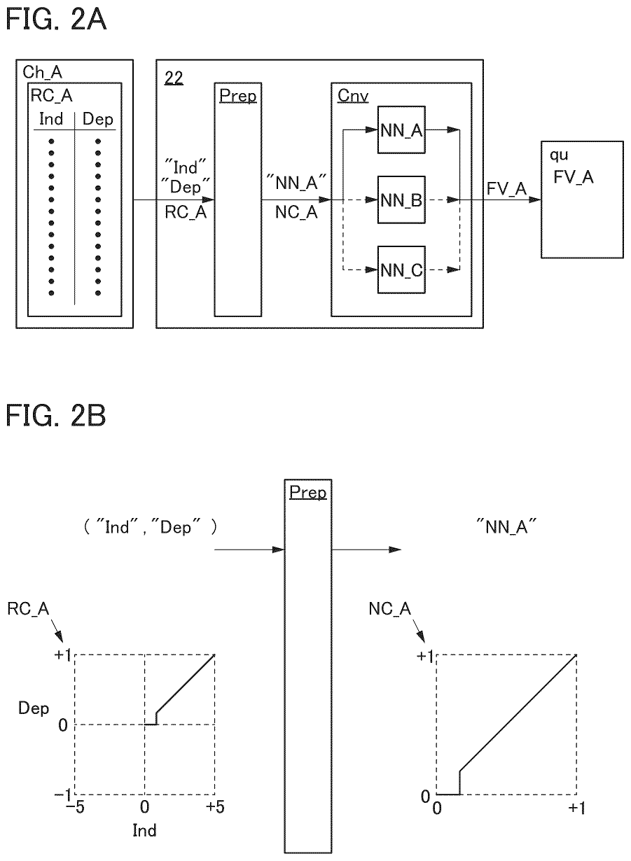

In this embodiment, a data processing system of one embodiment of the present invention will be described with reference to FIG. 1, FIGS. 2A and 2B, FIGS. 3A and 3B, FIGS. 4A and 4B, FIGS. 5A and 5B, FIG. 6, FIGS. 7A to 7C, FIGS. 8A to 8C, FIGS. 9A to 9D, and FIG. 10.

FIG. 1 illustrates a structure of the data processing system of one embodiment of the present invention.

FIG. 2A illustrates a structure and a function of a component 22 of the data processing system of one embodiment of the present invention, and FIG. 2B illustrates a function of a preprocessing portion Prep of the component 22.

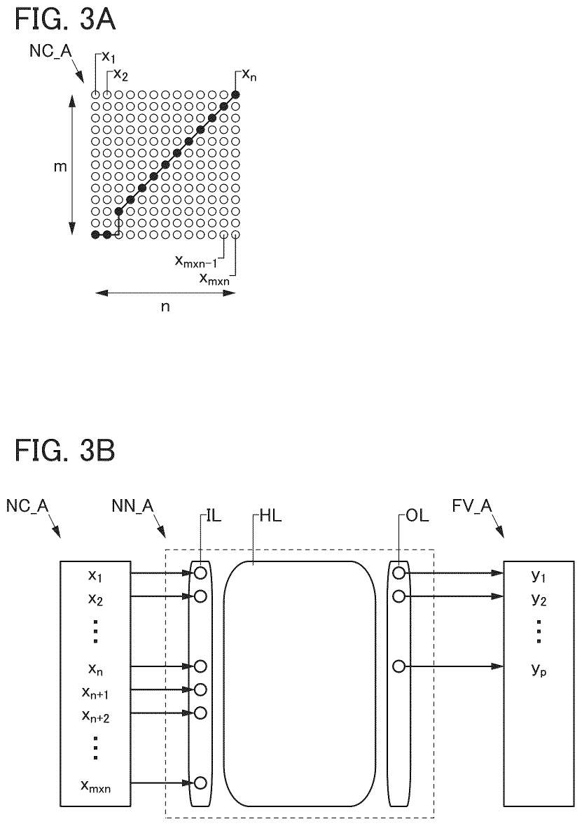

FIG. 3A illustrates a structure of a normalized curve NC_A that can be used for the data processing system of one embodiment of the present invention, and FIG. 3B illustrates a function of a converter NN_A in the data processing system of one embodiment of the present invention.

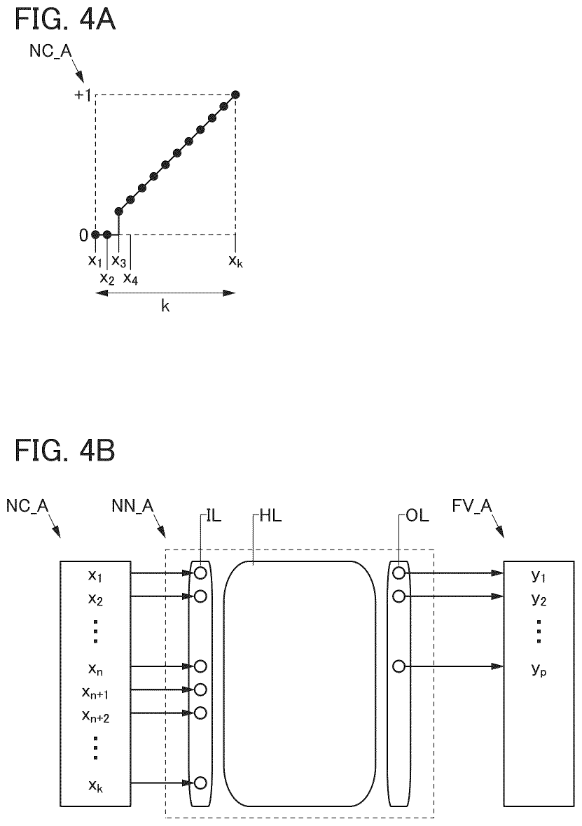

FIG. 4A illustrates a structure of the normalized curve NC_A that can be used for the data processing system of one embodiment of the present invention, and FIG. 4B illustrates a function of the converter NN_A that is different from the function described with reference to FIG. 3B.

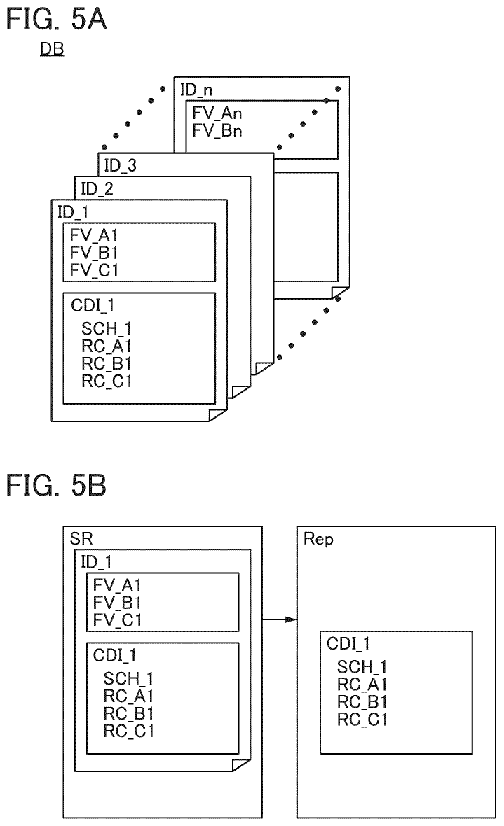

FIG. 5A illustrates a structure of a database that can be used for the data processing system of one embodiment of the present invention, and FIG. 5B illustrates a structure of a report Rep made by the data processing system of one embodiment of the present invention.

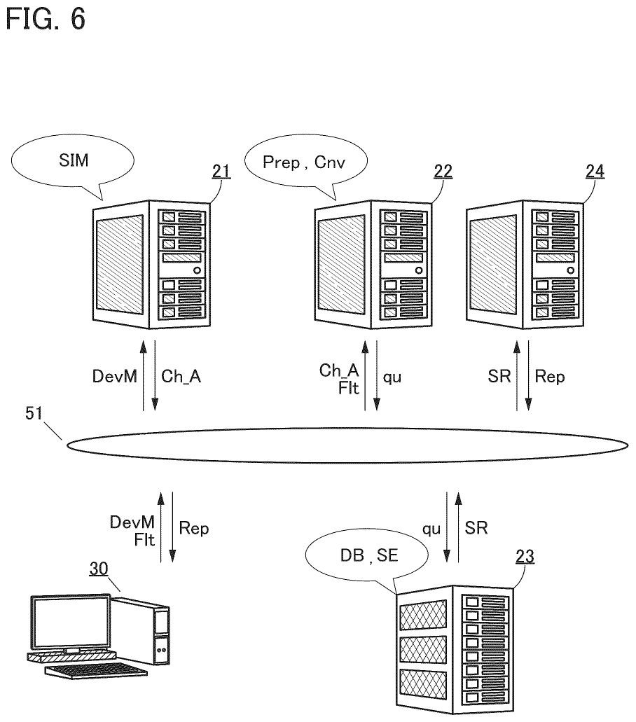

FIG. 6 illustrates a structure of the data processing system of one embodiment of the present invention.

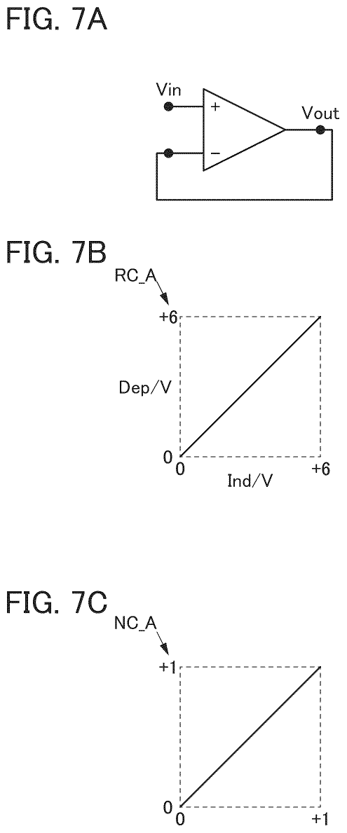

FIG. 7A illustrates a circuit symbol showing an example of an electronic circuit that can be searched using the data processing system of one embodiment of the present invention. FIG. 7B shows a response curve representing the operation characteristics of the electronic circuit illustrated in FIG. 7A, and FIG. 7C shows a normalized curve obtained by normalizing the response curve shown in FIG. 7B.

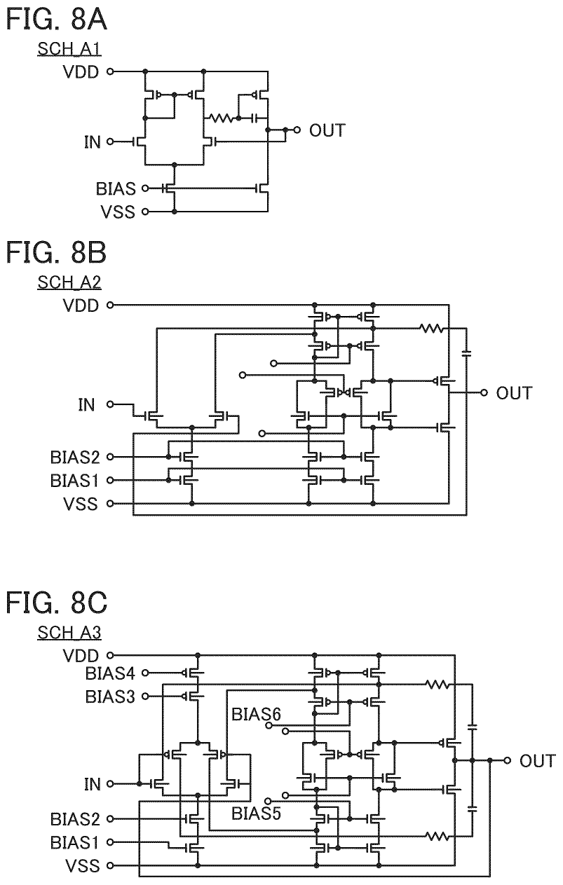

FIGS. 8A to 8C are circuit diagrams each showing a search result obtained using the data processing system of one embodiment of the present invention.

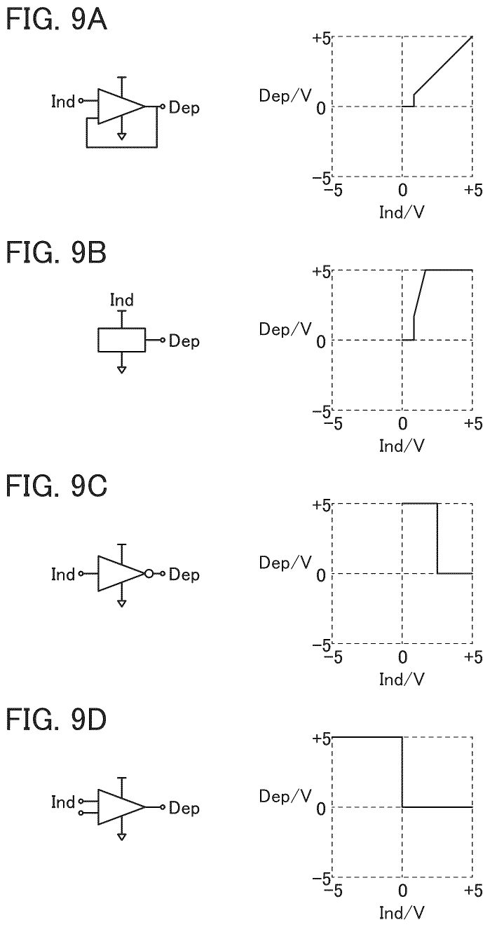

FIGS. 9A to 9D each show an example of a device model that can be searched using the data processing system of one embodiment of the present invention and a response curve that expresses the operation characteristics of the device model.

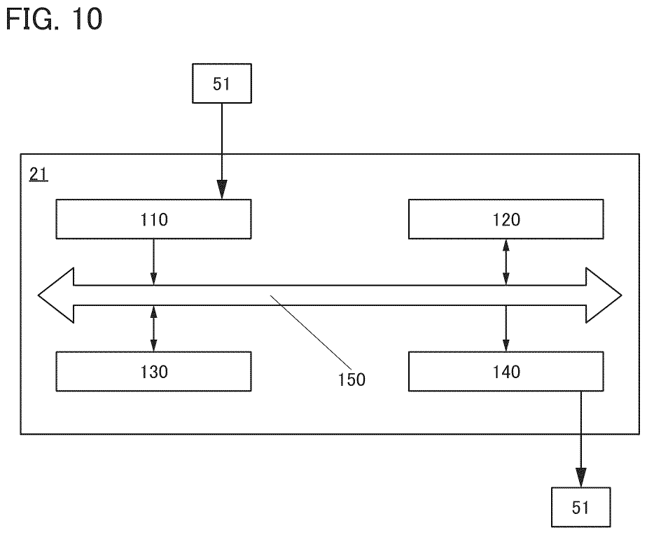

FIG. 10 is a block diagram illustrating a structure of a data processing device which can be used for the data processing system of one embodiment of the present invention.

### Structure Example 1 of Data Processing System

The data processing system described in this embodiment includes the component 22, a component 23, and a component 24 (see FIG. 1).

### Structure Example 1 of Component 22

The component 22 has a function of receiving characteristic information Ch_A (see FIG. 2A).

### Example 1 of Characteristic Information Ch_A

The characteristic information Ch_A includes a response curve RC_A. For example, the operation characteristics of an electronic circuit, specifically, the response of the electronic circuit to an input can be used for the response curve RC_A.

### Example 2 of Characteristic Information Ch_A

The operation specifications and the like of the electronic circuit can be included in the characteristic information Ch_A. Specifically, operation voltage, operation frequency, design specifications, or the like can be used as the characteristic information Ch_A. When a plurality of pieces of data are used as the characteristic information Ch_A, a plurality of conditions can be set in a query described later. Furthermore, when not only the response curve RC_A but also related data such as operation voltage, operation frequency, power consumption, or other design specifications of the electronic circuit, the name of a designer, design date and time, revision history, and a feature of the circuit are added, a narrowing retrieval can be performed.

### [Example of Response Curve RC_A]

The response curve RC_A includes an independent variable Ind and a dependent variable Dep. For example, the input can be regarded as the independent variable Ind, and the response can be regarded as the dependent variable Dep. The response curve RC_A can be represented using a matrix including two columns. Note that in the case where the response of the electronic circuit is used for the response curve RC_A, the range of the independent variable Ind is set so as to include the range of the design specifications. For example, the range of the design specifications and the range of the independent variable Ind match.

For example, when an input voltage is used as the independent variable Ind of the response curve RC_A and an output voltage is used as the dependent variable Dep, the response curve RC_A expresses the voltage-voltage characteristics of the electronic circuit.

For example, when an input voltage is used as the independent variable Ind of the response curve RC_A and an output current is used as the dependent variable Dep, the response curve RC_A expresses the voltage-current characteristics of the electronic circuit.

For example, when the time elapsed since a signal or power is supplied to the electronic circuit is used as the independent variable Ind of the response curve RC_A and the output voltage is used as the dependent variable Dep, the response curve RC_A expresses the time-voltage characteristics or transient voltage characteristics of the electronic circuit.

For example, when the time elapsed since a signal or power is supplied to the electronic circuit is used as the independent variable Ind of the response curve RC_A and the output current is used as the dependent variable Dep, the response curve RC_A expresses the time-current characteristics or transient current characteristics of the electronic circuit.

With the use of a combination of an independent variable and a dependent variable that express a response curve, the kind of the response curve of the electronic circuit can be identified. Note that, for example, the voltage-voltage characteristics, the voltage-current characteristics, the transient voltage characteristics, and the transient current characteristics are expressions that identify the kind of the response curve.

### Structure Example 2 of Component 22

The component 22 includes the preprocessing portion Prep and a conversion portion Cnv (see FIG. 2A).

### [Preprocessing Portion Prep]

The preprocessing portion Prep has a function of converting the response curve RC_A into the normalized curve NC_A (see FIG. 2B). Note that the normalized curve NC_A includes the independent variable Ind normalized in a predetermined range and the dependent variable Dep normalized in a predetermined range.

For example, when the independent variable Ind of the response curve RC_A is included in the range greater than or equal to 0 V and less than or equal to 5 V, the independent variable of the normalized curve NC_A can be normalized in the range greater than or equal to 0 and less than or equal to 1. When the dependent variable Dep of the response curve RC_A is included in the range greater than or equal to 0 V and less than or equal to 1 V, the normalized dependent variable of the normalized curve NC_A can be normalized in the range greater than or equal to 0 and less than or equal to 1. Thus, the size of the normalized curve NC_A can be adjusted.

### [Conversion Portion Cnv]

The conversion portion Cnv includes one or more converters. For example, the conversion portion Cnv includes the converter NN_A, a converter NN_B, and a converter NN_C. The conversion portion Cnv has a function of selecting the converter NN_A on the basis of the combination of the independent variable Ind and the dependent variable Dep of the response curve RC_A.

For example, the converter NN_A has a function of converting the normalized curve NC_A converted from the response curve RC_A into a feature vector FV_A (see FIG. 2B). The converter NN_B (not illustrated) has a function of converting a normalized curve converted from a response curve different from the response curve RC_A into a feature vector FV_B (not illustrated) different from the feature vector FV_A. The converter NN_C has a function of converting a normalized curve converted from a response curve different from the response curves RC_A and RC_B into a feature vector different from the feature vectors FV_A and FV_B. Note that a feature vector expresses a feature of a shape of a normalized curve using a vector.

Note that the kind of the response curve of the electronic circuit can be identified using a combination of an independent variable and a dependent variable that express a response curve. For example, the reference table can be referred to for a combination of the name of a column in which independent variables are stored and the name of a column in which dependent variables are stored to identify the kind of the response curve. Accordingly, the component 22 can select a converter in accordance with the kind of the response curve using the combination of the independent variable and the dependent variable of the response curve. When response curves of the same kind are compared, feature vectors converted using the same converter can be compared with each other.

### Example 1 of Converter NN_A

For example, the normalized curve NC_A can be divided into sections of m rows and n columns at predetermined intervals (see FIG. 3A). As for a section x₁, a section x₂, a section xₙ, a section x_{m×n-1}, a section x_{m×n}, and the like, the value of the section in which the normalized curve NC_A crosses is set to 1, and the value of the section in which the normalized curve NC_A does not cross is set to 0. In this manner, the normalized curve NC_A can be converted into a vector including m×n elements. Note that black circles in the drawing represent sections where the normalized curve NC_A crosses, and white circles in the drawing represent sections where the normalized curve NC_A does not cross.

A neural network can be used as the converter NN_A (see FIG. 3B). For example, a learned neural network used for image recognition can be used as the converter NN_A. Note that a learned neural network such as VGG16 or ResNet can be used for image recognition, for example.

The converter NN_A using a neural network includes an input layer IL, a hidden layer HL, and an output layer OL.

The input layer IL includes m×n nodes, for example, and a vector expressing the normalized curve NC_A can be input to the input layer IL.

The hidden layer HL can include a plurality of layers. For example, a fully connected layer and a convolutional layer can be used for the hidden layer HL.

The output layer OL includes nodes the number of which enables the features of the response curve RC_A to be expressed. For example, the number of nodes can be the same as the number of dimensions of a feature vector suitable for classification of the response curve RC_A.

### Example 2 of Converter NN_A

For example, the normalized curve NC_A can be divided into k points at predetermined intervals (see FIG. 4A). As for a point x₁, a point x₂, a point x₃, a point x₄, a point xx, and the like, the value of the normalized curve NC_A can be read and the normalized curve NC_A can be converted into a vector including k elements. In this case, a layer including k nodes can be used as the input layer (see FIG. 4B).

### Structure Example 3 of Component 22

The component 22 has a function of creating a query qu and transferring the query to the component 23 (see FIG. 2A). The query qu includes the feature vector FV_A.

### <<Structure Example of Component 23>>

The component 23 has a function of receiving the query qu, performing processing using a search engine SE, and transferring a search result SR to the component 24 (see FIG. 1).

The search engine SE has a function of obtaining the search result SR from a database DB in accordance with the query qu.

### [Database DB]

The database DB stores a record ID_1, a record ID_2, and a record ID_3 to a record ID_n (see FIG. 5A). Note that in the vector database, a similar record can be searched using a vector as a query.

The record ID_1 includes circuit design information CDI_1 and a feature vector FV_A1, a feature vector FV_B1, and a feature vector FV_C1 that are associated with the circuit design information CDI_1 (see FIG. 5A).

When the feature vector FV_A1 is similar to the feature vector FV_A, the search result SR includes the circuit design information CDI_1 (see FIG. 5B). For example, the Euclidean distance or cosine similarity between the feature vector FV_A1 and the feature vector FV_A can be used as the similarity scale. Note that as the Euclidean distance between two vectors is closer to 0, it can be said that the two vectors are more similar. In addition, as the cosine similarity is closer to 1, it can be said that the two vectors are more similar. Specifically, the cosine similarity is preferably 0.8 or more.

When the cosine similarity between the feature vector FV_A1 and the feature vector FV_A is calculated and the cosine similarity is greater than or equal to a predetermined value, it can be said that the feature vector FV_A1 is similar to the feature vector FV_A. Note that a plurality of records similar to one feature vector FV_A are included in the search result in some cases.

### Structure Example 1 of Component 24

The component 24 has a function of receiving the search result SR and making the report Rep (see FIG. 5B).

### Structure Example 1 of Report Rep

The report Rep includes the circuit design information CDI_1 (see FIG. 5B).

Thus, the database DB can be searched using the response curve RC_A. In addition, the circuit design information CDI_1 of a circuit that performs an operation similar to the operation represented by the response curve RC_A can be found from the database DB. For example, design information of a circuit designed in the past can be stored in the database DB and the circuit design information CDI_1 of the circuit that performs the operation similar to the operation represented by the response curve RC_A can be found. For example, the circuit design information disclosed in a document can be stored in the database DB and the circuit design information CDI_1 of the circuit that performs the operation similar to the operation represented by the response curve RC_A can be found. In addition, the past knowledge can be effectively used. As a result, a novel data processing system that is highly convenient, useful, or reliable can be provided.

### [Circuit Design Information CDI_1]

Note that the circuit design information CDI_1 includes a circuit diagram SCH_A1 and a response curve RC_A1 of the electronic circuit shown in the circuit diagram SCH_A1. The circuit design information CDI_1 includes a response curve RC_B1 and a response curve RC_C1. A variety of pieces of data can be included in the circuit design information CDI_1. For example, related data such as operation voltage, operation frequency, power consumption, or other design specifications of the electronic circuit, the name of a designer, design date and time, revision history, and a feature of the circuit can be included in the circuit design information CDI_1.

Note that the feature vector FV_A1 is obtained by converting the response curve RC_A1 using the converter NN_A. The feature vector FV_B1 is obtained by converting the response curve RC_B1 using the converter NN_B. The feature vector FV_C1 is obtained by converting the response curve RC_C1 using the converter NN_C.

### Structure Example 2 of Report Rep

The report Rep includes the circuit diagram SCH_A1 and the response curve RC_A1.

Thus, the circuit diagram SCH_A1 of a circuit that performs an operation similar to the operation represented by the response curve RC_A can be found from the database DB. The response curve RC_A1 can be viewed. For example, a circuit diagram of a circuit designed in the past can be stored in the database DB and the circuit diagram SCH_A1 of the circuit that performs the operation similar to the operation represented by the response curve RC_A can be found from the database DB. The response curve RC_A1 can be viewed. For example, circuit design information disclosed in a document can be stored in the database DB and the circuit diagram SCH_A1 of the circuit that performs the operation similar to the operation represented by the response curve RC_A can be found. The response curve RC_A1 can be viewed. In addition, the past knowledge can be effectively used. As a result, a novel data processing system that is highly convenient, useful, or reliable can be provided.

### Structure Example 2 of Data Processing System

The data processing system described in this embodiment includes a component 30, a component 21, the component 22, the component 23, and the component 24 (see FIG. 6). Note that the structure example 2 of the data processing system described in this embodiment is different from the structure example 1 of the data processing system in that the component 30 and the component 21 are included. Different portions are described in detail here, and the above description is referred to for portions that have similar structures.

### Structure Example 1 of Component 30

The component 30 has a function of receiving a device model DevM from a user of the data processing system, transferring the device model DevM to the component 21, receiving the report Rep, and providing the report Rep to the user of the data processing system.

For example, a circuit represented by a behavior-level hardware description language can be used as the device model DevM. Specifically, the description of the next paragraph using the SPICE model enables a voltage follower circuit illustrated in FIG. 7A to be expressed.
“X1 Vout Vin Vout Ideal_op_amp
.subckt Ideal_op_amp Vout Vinp Vinm
G1 Vout 0 Vout Vin 1MEG
RL Vout 0 1
.ends”.

### <<Structure Example of Component 21>>

The component 21 has a function of receiving the device model DevM, performing processing using an electronic circuit simulator SIM, and transferring the characteristic information Ch_A to the component 22.

The electronic circuit simulator SIM has a function of generating the characteristic information Ch_A from the device model DevM. The characteristic information Ch_A includes the response curve RC_A (see FIG. 7B).

Note that the preprocessing portion Prep of the component 22 converts the response curve RC_A into the normalized curve NC_A (see FIG. 7C).

### Structure Example 2 of Component 24

The component 24 has a function of transferring the report Rep to the component 30. For example, the report Rep includes the circuit diagram SCH_A1, a circuit diagram SCH_A2, and a circuit diagram SCH_A3 (see FIGS. 8A to 8C).

Thus, the response curve RC_A can be generated using the electronic circuit simulator SIM. The response curve RC_A can be generated from the device model DevM. In addition, the database DB can be searched using the generated response curve RC_A. In addition, the circuit design information CDI_1 of the circuit that performs the operation similar to the operation represented by the generated response curve RC_A can be found from the database DB. The report Rep that includes the circuit design information CDI_1 found from the database DB can be displayed on the component 30. In addition, the past knowledge can be effectively used. As a result, a novel data processing system that is highly convenient, useful, or reliable can be provided.

Note that a variety of device models can be transferred to the component 21 (see FIGS. 9A to 9D). FIG. 9A shows a voltage follower circuit and its operation characteristics. FIG. 9B shows a power supply circuit and its operation characteristics. FIG. 9C shows an inverter circuit and its operation characteristics. FIG. 9D shows a comparator circuit and its operation characteristics.

### Structure Example 2 of Component 30

The component 30 has a function of receiving a narrowing condition Flt and transferring the narrowing condition Flt to the component 22 (see FIG. 6). For example, as a result of searching the database DB using the response curve RC_A generated from the device model DevM, many unnecessary search results are included in the report Rep in some cases. The user of the data processing system of one embodiment of the present invention can add the narrowing condition Flt to the search condition. Specifically, data included in the circuit design information can be used for the narrowing condition Flt.

### Structure Example 4 of Component 22

The component 22 has a function of receiving the narrowing condition Flt. The query qu includes the narrowing condition Flt. When the narrowing condition Flt is added to the query, a narrowing retrieval can be performed.

Accordingly, the circuit design information CDI_1 of the circuit that performs the operation similar to the operation of the generated response curve RC_A can be found from the database DB, and the circuit design information CDI_1 that further satisfies the narrowing condition Flt can be found. The report Rep including the circuit design information CDI_1 found from the database DB can be displayed on the component 30. In addition, the past knowledge can be effectively used. As a result, a novel data processing system that is highly convenient, useful, or reliable can be provided.

### Structure Example 3 of Data Processing System

The data processing system described in this embodiment includes the component 22, the component 23, and the component 24 (see FIG. 1).

For example, the data processing system of one embodiment of the present invention can be constituted by a data processing device having a function of the component 22, a data processing device having a function of the component 23, and a data processing device having a function of the component 24. Note that the number of data processing devices constituting the data processing system of one embodiment of the present invention is one or more. For example, a plurality of data processing devices can be connected to each other using a network 51 to construct the data processing system of one embodiment of the present invention.

When the data processing system of one embodiment of the present invention is constituted with the use of the plurality of data processing devices, loads relating to data processing can be dispersed.

### Structure Example 1 of Data Processing Device

A data processing device with the structure example 1 described in this embodiment can be used for the component 22. For example, a workstation, a server computer, or a supercomputer can be used as the component 22.

The data processing device with the structure example 1 preferably has a function of a parallel computer. When the data processing device with the structure example 1 is used as a parallel computer, large-scale computation necessary for artificial intelligence (AI) learning and inference can be performed, for example.

The data processing device with the structure example 1 can perform processing using a neural network.

### Structure Example 2 of Data Processing Device>>

For example, a data processing device with the structure example 2 described in this embodiment can be used for the component 23. For example, a workstation, a server computer, or a supercomputer can be used as the component 23.

The data processing device with the structure example 2 can perform processing using a search engine. The data processing device with the structure example 2 has a larger memory capacity than the data processing device with the structure example 1.

### Structure Example 3 of Data Processing Device

For example, a data processing device with the structure example 3 described in this embodiment can be used for the component 24. For example, a workstation, a server computer, or a supercomputer can be used as the component 24.

For example, a web server or an application server can be used for the data processing device with the structure example 3.

### <<Structure Example of Network 51>>

The network 51 that can be used for the data processing system of one embodiment of the present invention can connect the plurality of data processing devices to each other. Thus, the plurality of data processing devices connected to each other can transmit and receive data to and from each other. Furthermore, loads of the data processing can be dispersed.

Note that for wireless communication, it is possible to use, as a communication protocol or a communication technology, a communication standard such as the fourth-generation mobile communication system (4G), the fifth-generation mobile communication system (5G), or the sixth-generation mobile communication system (6G), or a communication standard developed by IEEE such as Wi-Fi (registered trademark) or Bluetooth (registered trademark).

For example, a local network can be used as the network 51. An intranet or an extranet can also be used as the network 51. For another example, a personal area network (PAN), a local area network (LAN), a campus area network (CAN), a metropolitan area network (MAN), a wide area network (WAN), or a global area network (GAN) can be used as the network 51.

For example, a global network can be used as the network 51. Specifically, the Internet, which is an infrastructure of the World Wide Web (WWW), can be used.

Furthermore, the service provider using the data processing system of one embodiment of the present invention can provide service using the data processing method of one embodiment of the present invention via the network 51, for example.

Note that in the case where the data processing system of one embodiment of the present invention is constructed in a local network, the possibility of leakage of confidential information can be lower than that in the case of using the Internet, for example.

### Structure Example 4 of Data Processing System

The data processing system described in this embodiment includes the component 30 and the component 21 (see FIG. 6).

### Structure Example 4 of Data Processing Device

A data processing device with the structure example 4 described in this embodiment can be used for the component 30. The data processing device with the structure example 4 can also be referred to as a client computer or the like. For example, a desktop computer can be used as the component 30.

The data processing device with the structure example 4 can receive data input by the user of the data processing system of one embodiment of the present invention. Moreover, the data processing device with the structure example 4 can provide the user with data output from the data processing system of one embodiment of the present invention.

For example, dedicated application software or a web browser operates. The user of the data processing system of one embodiment of the present invention can access the data processing system via either of them. Thus, the user can receive service using the data processing system of one embodiment of the present invention.

### Structure Example 5 of Data Processing Device

A data processing device with the structure example 5 described in this embodiment can be used for the component 21. For example, a workstation, a server computer, or a supercomputer can be used as the component 21.

For example, a data processing device in which an electronic design automation (EDA) tool is installed can be used for the data processing device with the structure example 5.

### Structure Example 6 of Data Processing Device

The data processing device that can be used for the data processing system of one embodiment of the present invention includes, for example, an input portion 110, a storage portion 120, a processing portion 130, an output portion 140, and a transmission path 150 (see FIG. 10).

Although the block diagram in drawings attached to this specification illustrates components classified by their functions in independent blocks, it is difficult to classify actual components by their functions completely, and one component can have a plurality of functions. For example, part of the processing portion 130 functions as the input portion 110 in some cases. In addition, one function can be involved in a plurality of components. For example, processing executed by the processing portion 130 may be executed in different servers depending on processing content.

### [Input Portion 110]

The input portion 110 can receive data from the outside of the data processing device. For example, the input portion 110 receives data via the network 51.

The input portion 110 supplies the received data to one or both of the storage portion 120 and the processing portion 130 via the transmission path 150.

### [Storage Portion 120]

The storage portion 120 has a function of storing a program to be executed by the processing portion 130. The storage portion 120 can also have a function of storing data generated by the processing portion 130 (e.g., an arithmetic operation result, an analysis result, or an inference result), data received by the input portion 110, and the like.

The storage portion 120 can include a database. The data processing device can include a database in addition to the storage portion 120. The data processing device can have a function of extracting data from a database outside the storage portion 120, the data processing device, or the data processing system. Alternatively, the data processing device can have a function of extracting data from both of its own database and an external database.

One or both of a storage and a file server can be used as the storage portion 120. In addition, a database in which a path of a file stored in the file server is recorded can be used as the storage portion 120.

The storage portion 120 includes at least one of a volatile memory and a nonvolatile memory. Examples of the volatile memory include a dynamic random access memory (DRAM) and a static random access memory (SRAM). Examples of the nonvolatile memory include a resistive random access memory (ReRAM, also referred to as a resistance-change memory), a phase change random access memory (PRAM), a ferroelectric random access memory (FeRAM), a magnetoresistive random access memory (MRAM, also referred to as a magnetoresistive memory), and a flash memory. The storage portion 120 can include at least one of a NOSRAM (registered trademark) and a DOSRAM (registered trademark). The storage portion 120 can include a storage media drive. Examples of the storage media drive include a hard disk drive (HDD) and a solid state drive (SSD).

Note that “NOSRAM” is an abbreviation for “nonvolatile oxide semiconductor random access memory (RAM)”. The NOSRAM refers to a memory in which a 2-transistor (2T) or 3-transistor (3T) gain cell is used as a memory cell and the transistor includes a metal oxide in its channel formation region (such a transistor is also referred to as an OS transistor). The OS transistor has an extremely low current that flows between a source and a drain in an off state, that is, an extremely low leakage current. The NOSRAM can be used as a nonvolatile memory by retaining electric charge corresponding to data in memory cells, using characteristics of extremely low leakage current. In particular, the NOSRAM is capable of reading retained data without destruction (non-destructive reading), and thus is suitable for arithmetic processing in which only a data reading operation is repeated many times. The NOSRAM can have large data capacity when being stacked in layers; accordingly, when the NOSRAM is used as a large-scale cache memory, a main memory, or a storage memory, the performance of the semiconductor device can be increased.

The DOSRAM is an abbreviation for “dynamic oxide semiconductor RAM”, which is a RAM including a ITIC (one-transistor/one-capacitor) memory cell. The DOSRAM is a DRAM formed using an OS transistor, which temporarily stores data sent from the outside. The DOSRAM is a memory utilizing low off-state current of OS transistors.

In this specification and the like, a metal oxide means an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases.

The metal oxide included in the channel formation region preferably contains indium (In). When the metal oxide included in the channel formation region is a metal oxide containing indium, the carrier mobility (electron mobility) of the OS transistor is high. The metal oxide included in the channel formation region is preferably an oxide semiconductor including an element M. The element M is preferably at least one of aluminum (Al), gallium (Ga), and tin (Sn). Other elements that can be used as the element M are boron (B), silicon (Si), titanium (Ti), iron (Fe), nickel (Ni), germanium (Ge), yttrium (Y), zirconium (Zr), molybdenum (Mo), lanthanum (La), cerium (Ce), neodymium (Nd), hafnium (Hf), tantalum (Ta), tungsten (W), and the like. Note that a combination of two or more of the above elements may be used as the element M. The element M is, for example, an element that has high bonding energy with oxygen. The element M is, for example, an element that has higher bonding energy with oxygen than indium is. The metal oxide included in the channel formation region is preferably a metal oxide containing zinc (Zn). The metal oxide containing zinc is easily crystallized in some cases.

The metal oxide included in the channel formation region is not limited to the metal oxide containing indium. The metal oxide in the channel formation region may be, for example, a metal oxide that does not contain indium and contains any of zinc, gallium, and tin (e.g., zinc tin oxide and gallium tin oxide).

### [Processing Portion 130]

The processing portion 130 has a function of performing processing such as arithmetic operation, analysis, and inference with the use of data supplied from one or both of the input portion 110 and the storage portion 120. The processing portion 130 can supply generated data (e.g., an arithmetic operation result, an analysis result, or an inference result) to one or both of the storage portion 120 and the output portion 140.

The processing portion 130 has a function of obtaining data from the storage portion 120. The processing portion 130 can also have a function of storing or registering data in the storage portion 120.

The processing portion 130 can include an arithmetic circuit, for example. The processing portion 130 can include, for example, a central processing unit (CPU). The processing portion 130 can also include a graphics processing unit (GPU). Furthermore, the processing portion 130 can include a neural processing unit/neural network processing unit (NPU).

The processing portion 130 can include a microprocessor such as a digital signal processor (DSP). The microprocessor can be achieved with a programmable logic device (PLD) such as a field programmable gate array (FPGA) or a field programmable analog array (FPAA). The processing portion 130 can also include a quantum processor. With a processor, the processing portion 130 can interpret and execute instructions from various kinds of programs to process various kinds of data and control programs. The programs to be executed by the processor are stored in at least one of the storage portion 120 and a memory region of the processor.

The processing portion 130 can include a main memory. The main memory includes at least one of a volatile memory such as RAM and a nonvolatile memory such as a read only memory (ROM). The main memory can include at least one of the above-described NOSRAM and DOSRAM.

Examples of the RAM include a DRAM and an SRAM; a virtual memory space is assigned and utilized as a working space of the processing portion 130. An operating system, an application program, a program module, program data, a look-up table, and the like which are stored in the storage portion 120 are loaded into the RAM for execution. The data, program, and program module which are loaded into the RAM are each directly accessed and operated by the processing portion 130.

The ROM can store a basic input/output system (BIOS), firmware, and the like for which rewriting is not needed. Examples of the ROM include a mask ROM, a one-time programmable read only memory (OTPROM), and an erasable programmable read only memory (EPROM). Examples of the EPROM include an ultra-violet erasable programmable read only memory (UV-EPROM) which can erase stored data by irradiation with ultraviolet rays, an electrically erasable programmable read only memory (EEPROM), and a flash memory.

The processing portion 130 can include one or both of an OS transistor and a transistor including silicon in its channel formation region (Si transistor).

The processing portion 130 preferably includes an OS transistor. The OS transistor has an extremely low off-state current; thus, with the use of the OS transistor as a switch for retaining electric charge (data) that has flowed into a capacitor functioning as a memory element, a long data retention period can be ensured. When at least one of a register and a cache memory included in the processing portion has such a feature, the processing portion can be operated only when needed, and otherwise can be off while data processed immediately before turning off the processing portion is stored in the memory element. In other words, normally-off computing is possible and the power consumption of the data processing system can be reduced.

The data processing device preferably uses AI for at least part of its processing.

In particular, the data processing device preferably uses an artificial neural network (ANN; hereinafter also simply referred to as a neural network). The neural network can be constructed with circuits (hardware) or programs (software).

In this specification and the like, the neural network indicates a general model having the capability of solving problems, which is modeled on a biological neural network and determines the connection strength of neurons by learning. The neural network includes an input layer, a middle layer (hidden layer), and an output layer.

In the description of the neural network in this specification and the like, determining a connection strength of neurons (also referred to as weight coefficients) from the existing information is referred to as “learning” in some cases.

In this specification and the like, drawing a new conclusion from a neural network formed with the connection strength obtained by learning is referred to as “inference” in some cases.

### [Output Portion 140]

The output portion 140 can output at least one of an arithmetic operation result, an analysis result, and an inference result in the processing portion 130 to the outside of the data processing device. For example, the output portion 140 can transmit data via the network 51.

[Transmission path 150] The transmission path 150 has a function of transmitting data. Data transmission and reception between the input portion 110, the storage portion 120, the processing portion 130, and the output portion 140 can be performed via the transmission path 150.

Note that this embodiment can be combined with any of the other embodiments in this specification as appropriate.

### Embodiment 2

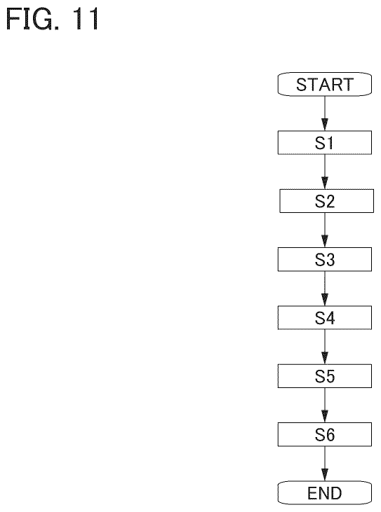

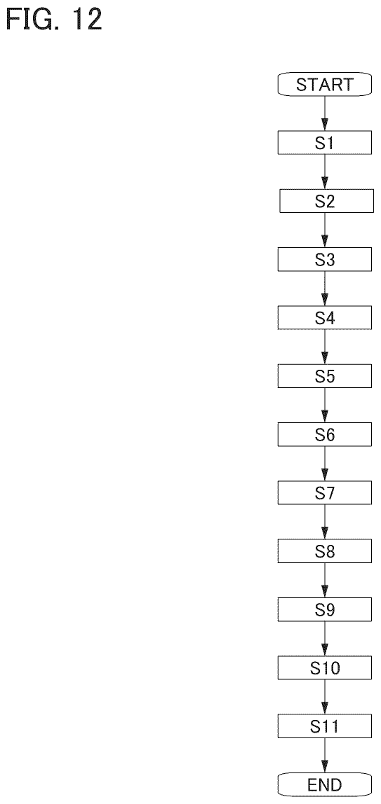

In this embodiment, a data processing method of one embodiment of the present invention will be described with reference to FIG. 11 and FIG. 12.

FIG. 11 illustrates a data processing method of one embodiment of the present invention.

FIG. 12 illustrates another data processing method of one embodiment of the present invention.

### Example 1 of Data Processing Method

The data processing method of one embodiment of the present invention includes Step S1 to Step S6 described below (see FIG. 11).

### [Step S1]

In Step S1, the component 22 receives the characteristic information Ch_A. Note that the characteristic information Ch_A includes the response curve RC_A, and the response curve RC_A includes the independent variable Ind and the dependent variable Dep.

### [Step S2]

In Step S2, the component 22 selects the converter NN_A on the basis of the combination of the independent variable Ind and the dependent variable Dep. Note that the converter NN_A has a function of converting the response curve RC_A into the feature vector FV_A.

### [Step S3]

In Step S3, the component 22 creates the query qu and transfers the query qu to the component 23. Note that the query qu includes the feature vector FV_A.

### [Step S4]

In Step S4, the component 23 receives the query qu. Furthermore, the component 23 obtains the search result SR from the database DB in accordance with the query qu using the search engine SE.

Note that the database DB stores the record ID_1. The record ID_1 includes the circuit design information CDI_1 and the feature vector FV_A1 associated with the circuit design information CDI_1. When the feature vector FV_A1 is similar to the feature vector FV_A, the search result SR includes the circuit design information CDI_1.

### [Step S5]

In Step S5, the component 23 transfers the search result SR to the component 24.

### [Step S6]

In Step S6, the component 24 receives the search result SR and makes the report Rep from the search result SR. Note that the report Rep includes the circuit design information CDI_1.

Thus, the database DB can be searched using the response curve RC_A. In addition, the circuit design information CDI_1 of the circuit that performs the operation similar to the operation represented by the response curve RC_A can be found from the database DB. For example, design information of a circuit designed in the past can be stored in the database DB, and the circuit design information CDI_1 of the circuit that performs the operation similar to the operation represented by the response curve RC_A can be found. For example, circuit design information disclosed in a document can be stored in the database DB, and the circuit design information CDI_1 of the circuit that performs the operation similar to the operation represented by the response curve RC_A can be found. In addition, the past knowledge can be effectively used. As a result, a novel data processing method that is highly convenient, useful, or reliable can be provided.

### Example 2 of Data Processing Method

The data processing method of one embodiment of the present invention includes Step S1 to Step S11 described below (see FIG. 12).

### [Step S1]

In Step S1, the component 30 receives the device model DevM from the user of the data processing system and transfers the device model DevM to the component 21.

### [Step S2]

In Step S2, the component 21 receives the device model DevM and generates the response curve RC_A using the electronic circuit simulator SIM.

### [Step S3]

In Step S3, the component 21 transfers the response curve RC_A to the component 22.

### [Step S4]

In Step S4, the component 22 receives the characteristic information Ch_A. Note that the characteristic information Ch_A includes the response curve RC_A, and the response curve RC_A includes the independent variable Ind and the dependent variable Dep.

### [Step S5]

In Step S5, the component 22 selects the converter NN_A on the basis of the combination of the independent variable Ind and the dependent variable Dep. Note that the converter NN_A has a function of converting the response curve RC_A into the feature vector FV_A.

### [Step S6]

In Step S6, the component 22 creates the query qu and transfers the query qu to the component 23. Note that the query qu includes the feature vector FV_A.

### [Step S7]

In Step S7, the component 23 receives the query qu. Furthermore, the component 23 obtains the search result SR from the database DB in accordance with the query qu using the search engine SE.

Note that the database DB stores the record ID_1. The record ID_1 includes the circuit design information CDI_1 and the feature vector FV_A1 associated with the circuit design information CDI_1. When the feature vector FV_A1 is similar to the feature vector FV_A, the search result SR includes the circuit design information CDI_1.

### [Step S8]

In Step S8, the component 23 transfers the search result SR to the component 24.

### [Step S9]

In Step S9, the component 24 receives the search result SR and generates the report Rep from the search result SR. Note that the report Rep includes the circuit design information CDI_1.

### [Step S10]

In step S10, the component 24 transfers the report Rep to the component 30.

### [Step S11]

In Step S11, the component 30 receives the report Rep and provides the report Rep to the user of the data processing system.

Thus, the response curve RC_A can be generated using the electronic circuit simulator SIM. The response curve RC_A can be generated from the device model DevM. In addition, the database DB can be searched using the generated response curve RC_A. In addition, the circuit design information CDI_1 of the circuit that performs the operation similar to the operation represented by the generated response curve RC_A can be found from the database DB. The report Rep including the circuit design information CDI_1 found from the database DB can be displayed on the component 30. In addition, the past knowledge can be effectively used. As a result, a novel data processing method that is highly convenient, useful, or reliable can be provided.

Note that this embodiment can be combined with any of the other embodiments in this specification as appropriate.

This application is based on Japanese Patent Application Serial No. 2023-220980 filed with Japan Patent Office on Dec. 27, 2023, the entire contents of which are hereby incorporated by reference.

What is claimed is:

1. A data processing system comprising:
a first component comprising a preprocessing portion and a conversion portion;
a second component; and
a third component,
wherein the first component is configured to receive characteristic information comprising a first response curve,
wherein the first response curve comprises an independent variable and a dependent variable,
wherein the preprocessing portion is configured to convert the first response curve into a normalized curve,
wherein the conversion portion is configured to select a converter on the basis of a combination of the independent variable and the dependent variable,
wherein the converter is configured to convert the normalized curve into a first feature vector,
wherein the normalized curve comprises the independent variable normalized in a first predetermined range and the dependent variable normalized in a second predetermined range,
wherein the first component is configured to create a query comprising the first feature vector and to transfer the query to the second component,
wherein the second component is configured to perform processing using a search engine,
wherein the search engine is configured to obtain a search result from a database in accordance with the query,
wherein the database is configured to store a record,
wherein the record comprises circuit design information and a second feature vector associated with the circuit design information,
wherein the search result comprises the circuit design information associated with the second feature vector which is similar to the first feature vector,
wherein the second component is configured to transfer the search result to the third component, and
wherein the third component is configured to present the search result to a user of the data processing system.

2. The data processing system according to claim 1, wherein the circuit design information comprises a circuit diagram.

3. The data processing system according to claim 2, wherein the circuit design information comprises a second response curve of an electronic circuit shown in the circuit diagram.

4. The data processing system according to claim 3, further comprising:
a fourth component; and
a fifth component,
wherein the fourth component is configured to receive a device model,
wherein the fourth component is configured to transfer the device model to the fifth component,
wherein the fifth component is configured to perform processing using an electronic circuit simulator and to transfer the characteristic information to the first component, and
wherein the electronic circuit simulator is configured to generate the characteristic information from the device model.

5. The data processing system according to claim 4,
wherein the fourth component is configured to receive a narrowing condition and to transfer the narrowing condition to the first component, and
wherein the query comprises the narrowing condition.

6. A data processing method comprising:
a first step in which a first component receives characteristic information comprising a response curve, the response curve comprising an independent variable and a dependent variable;
a second step in which the first component selects a converter on the basis of a combination of the independent variable and the dependent variable, the converter being configured to convert the response curve into a first feature vector;
a third step in which the first component creates a query and transfers the query comprising the first feature vector to a second component;
a fourth step in which the second component receives the query and obtains a search result from a database storing a record in accordance with the query using a search engine, the record comprising circuit design information and a second feature vector associated with the circuit design information;
a fifth step in which the second component transfers the search result comprising the circuit design information associated with the second feature vector which is similar to the first feature vector to a third component; and
a sixth step in which the third component receives the search result.

7. A data processing method comprising:
a first step in which a first component receives a device model and transfers the device model to a second component;
a second step in which the second component creates a response curve using an electronic circuit simulator;
a third step in which the second component transfers the response curve to a third component;
a fourth step in which the third component receives characteristic information comprising the response curve, the response curve comprising an independent variable and a dependent variable;
a fifth step in which the third component selects a converter on the basis of a combination of the independent variable and the dependent variable, the converter being configured to convert the response curve into a first feature vector;
a sixth step in which the third component creates a query comprising the first feature vector and transfers the query to a fourth component;
a seventh step in which the fourth component obtains a search result from a database, comprising circuit design information and a second feature vector associated with the circuit design information, in accordance with the query using a search engine, the search result comprising the circuit design information associated with the second feature vector which is similar to the first feature vector;
an eighth step in which the fourth component transfers the search result to a fifth component;
a ninth step in which the fifth component creates a report from the search result comprising the circuit design information;
a tenth step in which the fifth component transfers the report to the first component; and
an eleventh step in which the first component provides the report.
